(19) United States
(12) Patent Application Publication
(10) Pub. No.: US 2008/0153203 A1
(43) Pub. Date: Jun. 26, 2008

(54) SEMICONDUCTOR DEVICE MANUFACTURING METHOD

(75) Inventors: Hitoshi Sato, Nagano-shi (JP); Hidetoshi Inoue, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 11/962,212

(22) Filed: Dec. 21, 2007

(30) Foreign Application Priority Data
Dec. 22, 2006 (JP) 2006-346753

(51) Int. Cl. H01L 21/60

(52) U.S. Cl. 438/108; 257/E21.511

(57) ABSTRACT

In a method of manufacturing a semiconductor device, the method includes: a) preparing one type of an ASIC chip; b) preparing memory chips which are different from each other; c) preparing a common circuit substrate; d) preparing a pedestal terminal chip including wiring patterns having memory chip terminals and external connection terminals; e) mounting the ASIC chip on the common circuit substrate by flip-chip bonding; f) securing the pedestal terminal chip on the ASIC chip; g) mounting one of the memory chips on the pedestal terminal chip; h) electrically connecting terminals on the one of the memory chips to the memory chip terminals using a first wire; and i) electrically connecting the external connection terminals to terminals on the common circuit substrate using a second wire.

This application is based on and claims priority from Japanese Patent Application No. 2006-346753, filed on Dec. 22, 2006, the entire contents of which are hereby incorporated by reference.

### BACKGROUND OF THE INVENTION

1. Technical Field

The present disclosure relates to a semiconductor device manufacturing method.

2. Background Art

It is known that the semiconductor device configured by mounting an ASIC chip on a circuit substrate to be connected thereto and then stacking a memory chip on the ASIC chip when the ASIC chip and the memory chip for the ASIC chip are mounted on the circuit substrate(see e.g., Japanese Unexamined Patent Document: No. 2005-251953).

By the way, a plurality of different memory chips are provided to one type of ASIC chip. In this case, the memory chips must also be connected electrically to predetermined terminals on the circuit substrate through wire. In the case of different memory chips, normally positions of their terminals on the circuit substrate are different. Therefore, in the related-art, the circuit substrate must be designed every different memory chip respectively. As a result, there have been such problems that manufacture of such structure becomes troublesome and a production cost is increased.

For example, as shown in FIG. 15A, FIG. 16A, FIG. 17A, terminal arrangements are slightly different in memory chips 1, 2 and 3. In this case, as shown in FIG. 15B, FIG. 16B, FIG. 17B, as substrates 4, 5 and 6, the dedicated circuit substrates 4, 5 and 6 having the terminal arrangements that are fitted in with the terminal arrangements of the memory chips 1, 2 and 3 respectively must be designed and manufactured. Here, FIG. 15C, FIG. 16C, FIG. 17C are plan views showing the memory chip mounted on the substrate respectively, and FIG. 15D, FIG. 16D, FIG. 17D are front views showing the memory chip mounted on the substrate respectively, and 8 denotes the ASIC chip.

Also, in FIG. 18A to FIG. 18D, an example is shown that memory chips 10 having the same capacity are stacked in two layers and mounted on an ASIC chip 8. When a plurality of memory chips 10 are stacked and provided on a circuit substrate 12, the circuit substrate 12 in which dedicated terminals are particularly provided every stacked number of the memory chips 10 respectively must be designed and prepared. Here, 9 denotes a spacer formed of the insulating body.

Also, the circuit substrate 12 shown in FIG. 18B can be designed so that one memory chip is mounted on this circuit substrate. In this case, in order to respond to such a situation that a plurality of memory chips should be mounted, the circuit substrate having the terminal arrangement that can deal with the memory chips in the largest number must be prepared in advance. However, normally the circuit substrate has a multi-layered and complicated structure. As a result, there have been such problems that design and manufacture of the circuit substrate are not easy and also an increase in cost is caused.

### SUMMARY OF THE INVENTION

The present invention has been achieved to solve the above problem, and an object of the present invention provides a semiconductor device manufacturing method that can achieve a reduction of cost using a common circuit substrate.

According to a first aspect of the present invention, in a method of manufacturing a semiconductor device, a method of manufacturing a semiconductor device, the method comprises:

a) preparing one type of an ASIC chip;

b) preparing memory chips which are different from each other;

c) preparing a common circuit substrate;

d) preparing a pedestal terminal chip including wiring patterns having memory chip terminals and external connection terminals;

e) mounting the ASIC chip on the common circuit substrate by flip-chip bonding;

f) securing the pedestal terminal chip on the ASIC chip;

g) mounting one of the memory chips on the pedestal terminal chip;

h) electrically connecting terminals on said one of the memory chips to the memory chip terminals using a first wire; and

i) electrically connecting the external connection terminals to terminals on the common circuit substrate using a second wire.

According to a second aspect of the present invention, in a method of manufacturing a semiconductor device, the method comprises the steps of:

a) preparing one type of an ASIC chip;

b) preparing memory chips;

c) preparing a common circuit substrate;

d) preparing a pedestal terminal chip including wiring patterns having memory chip terminals and external connection terminals;

e) mounting the ASIC chip on the common circuit substrate by flip-chip bonding;

f) securing the pedestal terminal chip on the ASIC chip;

g) mounting the memory chips on the pedestal terminal chip;

h) electrically connecting terminals on the memory chips to the memory chip terminals using a first wire; and

i) electrically connecting the external connection terminals to terminals on the common circuit substrate using a second wire.

According to a third aspect of the present invention, wherein the step g) may comprise: stacking the memory chips via a spacer.

According to a fourth aspect of the present invention, the step g) may comprise: providing the memory chips in combination.

According to the present invention, the circuit substrate that entails much cost in design and manufacture is provided as the common one, and common or individual wiring patterns corresponding to a plurality of memory chips are provided on the pedestal terminal side that is easy to design and manufacture and does not relatively need a cost. Therefore, the semiconductor device capable of reducing a production cost can be provided.

### BRIEF DESCRIPTION OF THE DRAWINGS

FIGS. 1A to 1D are explanatory views showing a mounting example of a memory chip according to a first embodiment of the present invention;

FIGS. 2A to 2D are explanatory views showing another mounting example of the memory chip according to the first embodiment;

FIGS. 3A to 3D are explanatory views showing another mounting example of the memory chip according to the first embodiment;

FIG. 4 is an explanatory view of a circuit substrate according to the first embodiment;

FIGS. 5A to 5D are explanatory views of a memory chip according to a second embodiment of the present invention;

FIG. 6 is an explanatory view of a circuit substrate according to the second embodiment;

FIG. 7 is an explanatory view of a pedestal terminal chip according to the second embodiment;

FIG. 8 is a plan view of a semiconductor device according to the second embodiment;

FIG. 9 is a front view of a semiconductor device according to the second embodiment;

FIG. 10 is an explanatory view of a memory chip according to a third embodiment of the present invention;

FIG. 11 is an explanatory view of a circuit substrate according to the third embodiment;

FIG. 12 is an explanatory view of a pedestal terminal chip according to the third embodiment;

FIG. 13 is a plan view of a semiconductor device according to the third embodiment;

FIG. 14 is a front view of a semiconductor device according to the third embodiment;

FIGS. 15A to 15D are explanatory views showing a mounting example of a memory chip according to a semiconductor device in the related-art;

FIGS. 16A to 16D are explanatory views showing another mounting example of the memory chip according to the semiconductor device in the related-art;

FIGS. 17A to 17D are explanatory views showing another mounting example of the memory chip according to the semiconductor device in the related-art; and

FIGS. 18A to 18D are explanatory views showing another mounting example of the memory chip according to the semiconductor device in the related-art.

### DETAILED DESCRIPTION OF EXEMPLARY EMBODIMENTS

Next, exemplary embodiments will be described in detail with reference to the drawings hereinafter.

### First Embodiment

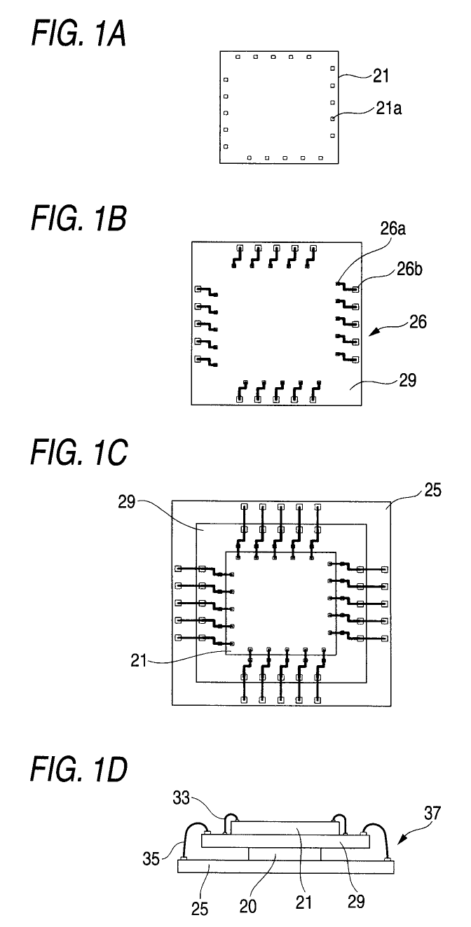

FIG. 1A to FIG. 3D show a first embodiment. The present embodiment shows an example in which three types of memory chips 21, 22 and 23 are mounted on one type of ASIC chip 20. Positions of terminals 21a, 22a and 23a are shifted in respective memory chips 21, 22 and 23. Namely, in this example, the terminals 21a of the memory chip 21 are shifted leftward relatively with respect to the terminals 22a of the memory chip 22, and the terminals 23a of the memory chip 23 are shifted rightward relatively with respect to the terminals 22a.

In such case, in the related-art, the circuit substrate whose terminal positions are designed to correspond to each memory chip is prepared individually.

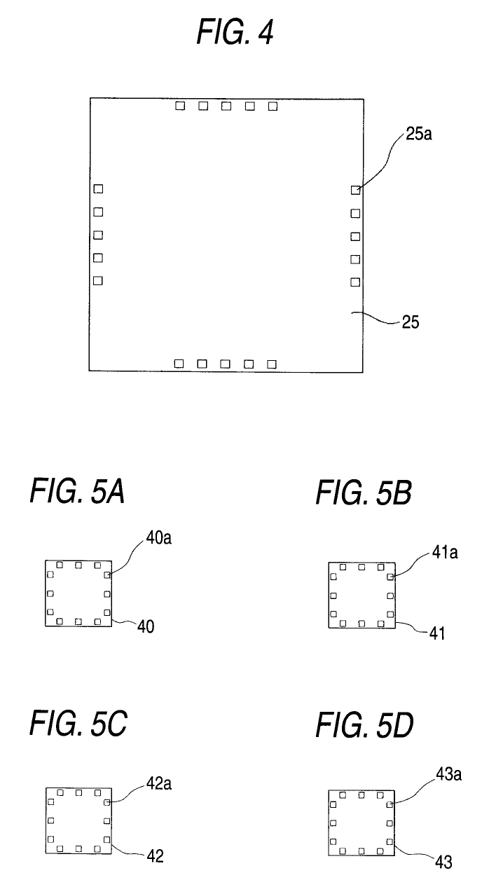

However, in the present embodiment, a common circuit substrate 25 whose positions of terminals 25a are set in common is employed (see FIG. 4).

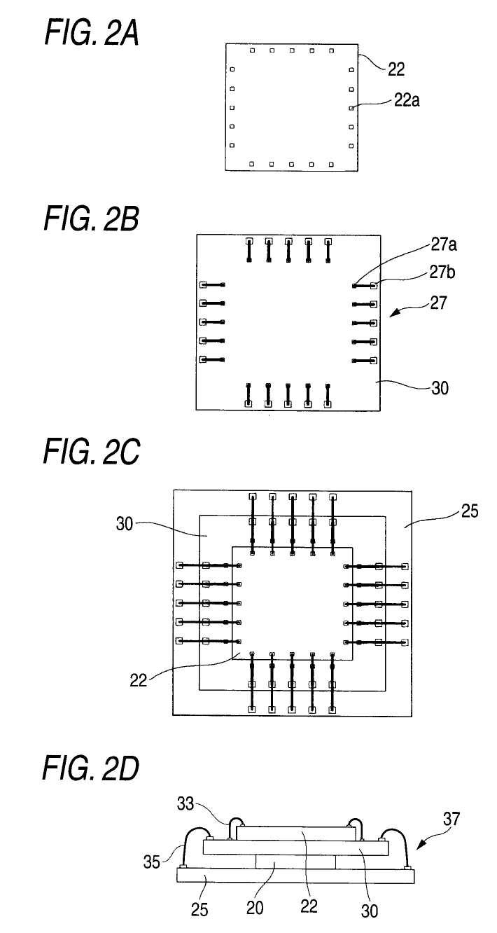

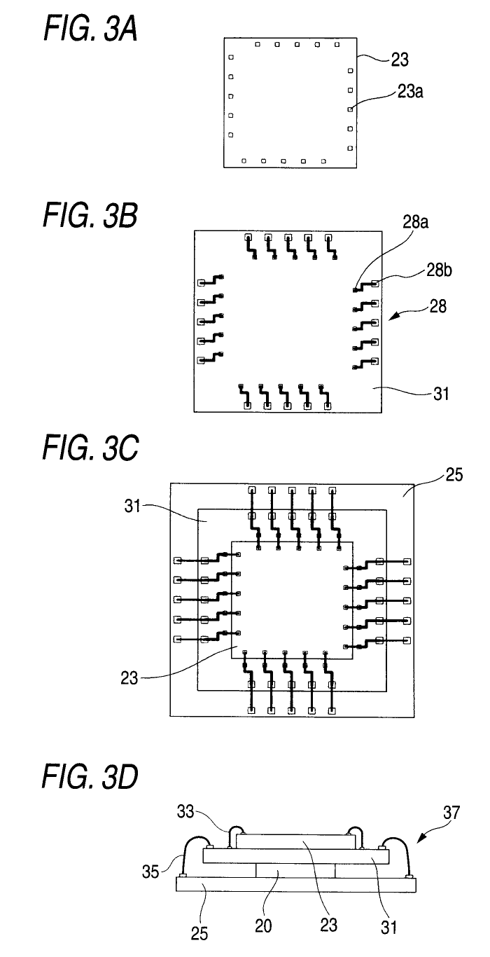

Also, in the present embodiment, as shown in FIG. 1B, FIG. 2B and FIG. 3B, pedestal terminal chips 29, 30 and 31—on which different memory chips 21, 22 and 23 can be mounted respectively and on which wiring patterns 26, 27 and 28 are formed respectively—are prepared every memory chip. The wiring patterns 26, 27 and 28 have memory chip terminals 26a, 27a and 28a to which the terminals 21a, 22a and 23a of the memory chips 21, 22 and 23 can be connected via wire respectively and external connection terminals 26b, 27b and 28b to which the terminals 25a of the circuit substrate 25 can be connected via wire respectively.

The memory chip terminals 26a, 27a and 28a of the pedestal terminal chips 29, 30 and 31 are provided in positions to which the terminals 21a, 22a and 23a of the memory chips 21, 22 and 23 to be mounted are easily connected via wire respectively, for example, in which both terminals are set closest mutually. Similarly, the external connection terminals 26b, 27b and 28b of the pedestal terminal chips 29, 30 and 31 are provided in positions to which the terminals 25a of the circuit substrate 25 are easily connected via wire respectively, for example, in which both terminals are set closest mutually.

The wiring patterns 26, 27 and 28 are formed on the pedestal terminal chips 29, 30 and 31 respectively such that the terminals 26a and 26b, the terminals 27a and 27b, and the terminals 28a and 28b are connected by these patterns respectively.

Only the wiring patterns 26, 27 and 28 having respective terminals are formed on the pedestal terminal chips 29, 30, 31. Therefore, design and manufacture of the pedestal terminal chips 29, 30 and 31 are carried out easily and at a low cost. Namely, the design and the manufacture of the pedestal terminal chips 29, 30, 31 are carried out more easily and at an extremely lower cost than the case where the multi-layered circuit substrate 25 is formed respectively. The pedestal terminal chips 29, 30 and 31 can be manufactured using a silicon wafer.

As described above, the circuit substrate 25 is employed commonly, but the pedestal terminal chips 29, 30 and 31 on which the memory chips 21, 22 and 23 can be mounted are prepared respectively.

Then, the ASIC chip 20 is flip-chip bonded to the circuit substrate 25, which is used in common with three sets of the ASIC chip 20 and the individual memory chips 21, 22 and 23, respectively. Then, the pedestal terminal chips 29, 30 and 31 are secured onto the ASIC chip 20 with an adhesive respectively Then, the corresponding memory chips 21, 22 and 23 are secured onto the pedestal terminal chips 29, 30 and 31 with an adhesive respectively.

Next, the terminals 21a, 22a and 23a of the memory chips 21, 22 and 23 are connected electrically to the corresponding memory chip terminals 26a, 27a and 28a of the pedestal terminal chips 29, 30 and 31 respectively. Then, the external connection terminals 26b, 27b and 28b of the pedestal terminal chips 29, 30 and 31 are connected electrically to the terminals 25a of the circuit substrate 25 via the wire 35 respectively thus to provide a semiconductor device 37 (see FIGS. 1C and 1D, FIGS. 2C and 2D, FIGS. 3C and 3D). Here, the ASIC chip 20, the memory chips, and wires 33 and 35 may be sealed by a sealing resin (not shown).

### Second Embodiment

FIG. 5 to FIG. 9 show a second embodiment. The present embodiment shows an example in which a plurality (up to four, for example) of memory chips that are smaller in size than the ASIC chip 20 are mounted. In the related-art, when one, two, three, and four memory chips are to be mounted individually, respective circuit substrates for one, two, three, and four memory chips are designed and manufactured separately.

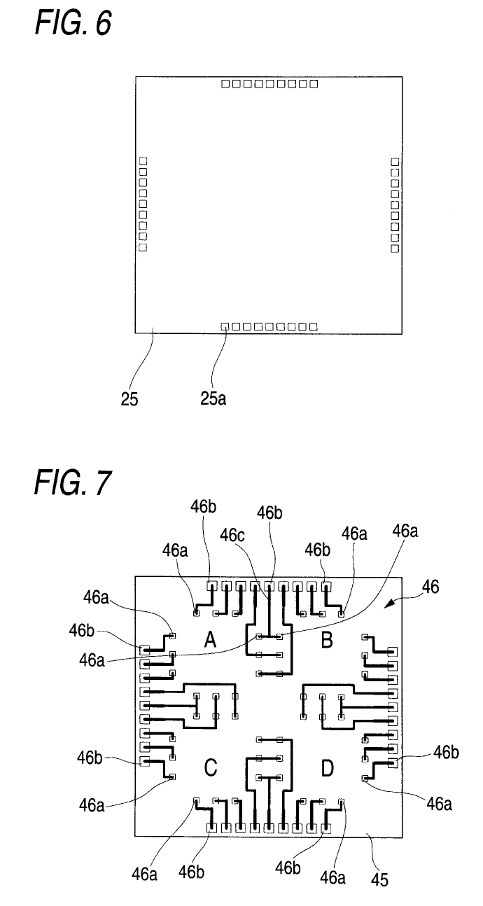

In the present embodiment, when the number of memory chips to be mounted is known in advance, the common circuit substrate 25 having an arrangement of the terminals 25a that can deal with respective memory chips from the minimum number to the maximum number is designed and manufactured previously (see FIG. 6).

In this example, the circuit substrate 25 that can respond to up to four memory chips 40, 41, 42 and 43 (FIG. 5) is prepared. In this case, as the memory chips 40, 41, 42 and 43, either of the same types and the different types may be used.

Further, in the present embodiment, a common pedestal terminal chip 45 on which a plurality (up to four, for example) of memory chips 40, 41, 42 and 43 can be mounted is prepared (FIG. 7). Also, wiring patterns 46 that are connected electrically to the memory chips to be mounted up to a maximum of four are formed on the pedestal terminal chip 45.

For example, areas A, B, C and D in FIG. 7 are areas on which the memory chips 40, 41, 42, 43 are mounted respectively. Memory chip terminals 46a to which terminal 40a, 41a, 42a and 43a of the memory chips 40, 41, 42 and 43 can be connected electrically via the wire 33 respectively are formed around these areas in predetermined arrangements.

Also, external connection terminals 46b connected to respective memory chip terminals 46a are formed in peripheral areas of the pedestal terminal chip 45 in predetermined arrangements. Both terminals 46a and 46b can be formed in desired positions in predetermined arrangements by leading the wiring patterns 46 therein.

The external connection terminals 46b are aligned such that these terminals can be connected to the terminals 25a of the circuit substrate 25 via the wire 35.

Several neighboring memory chips can be shared using the bus line, or the like. Therefore, two memory chip terminals 46a and 46a, to which common terminals of the neighboring memory chips are connected via the wire 33, are formed on a common wiring (e.g., 46c) on the pedestal terminal chip 45, and then these memory chip terminals 46a and 46a are connected to one external connection terminal 46b. Thus, the wiring patterns 46 are formed. In the example in FIG. 7, three common wirings 46c are formed between the neighboring memory chips. The pedestal terminal chip 45 can also be manufactured easily using a semiconductor wafer.

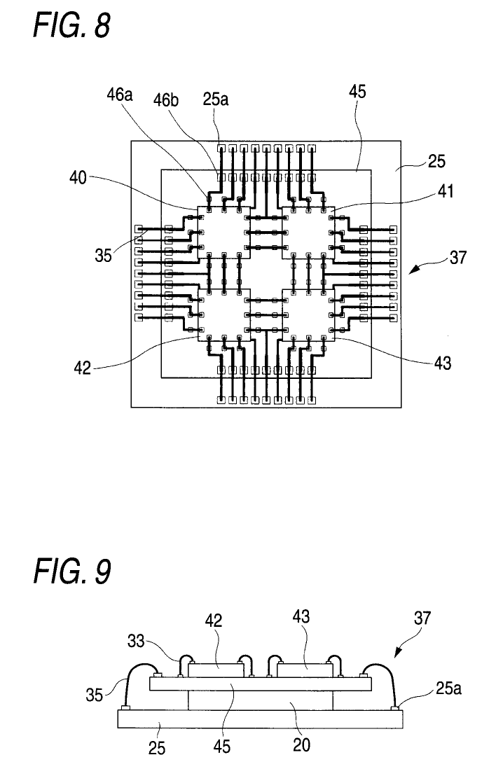

As described above, the circuit substrate 25 and the pedestal terminal chip 45 are prepared. First, the ASIC chip 20 is flip-chip bonded and thus mounted on the circuit substrate 25. Then, the pedestal terminal chip 45 is secured onto the ASIC chip 20 with an adhesive. Then, predetermined number (four in the illustrated example) of memory chips are secured onto the pedestal terminal chip in predetermined positions with an adhesive. Then, the terminals of the memory chips and the memory chip terminals 46a of the pedestal terminal chip 45 are connected electrically mutually by the wire 33. Then, the external connection terminals 46b of the pedestal terminal chip 45 and the terminals 25a of the circuit substrate 25 are connected electrically mutually by the wire 35. Thus, the semiconductor device 37 is completed with respect to respective memory chips (see FIG. 8 and FIG. 9). Here, the ASIC chip 20, the memory chips, and the wires 33 and 35 may be sealed by the sealing resin (not shown).

### Third Embodiment

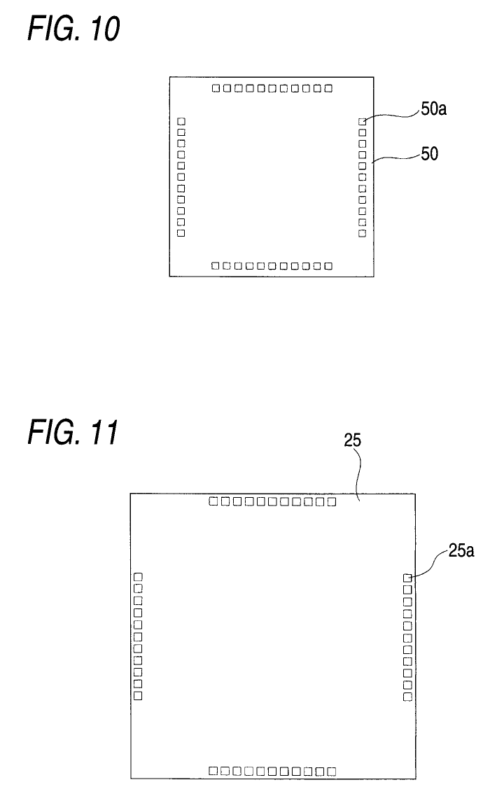

FIG. 10 to FIG. 14 show a third embodiment. The present embodiment shows an example in which a plurality of same memory chips 50 (FIG. 10) are mounted on one type of ASIC chip 20. Since the same memory chips 50 are employed, positions and functions of their terminals 50a are totally identical. In this example, the case where the memory chips 50 are mounted up to two pieces will be described hereunder.

In the present embodiment, the circuit substrate 25 having the common terminals 25a (FIG. 11) is prepared. In this case, the same arrangement as that employed when one memory chip 50 is mounted may be employed as the arrangement of the terminals 25a.

Also, in the present embodiment, a common pedestal terminal chip 52 on which a plurality of memory chips can be mounted is prepared. Then, a plurality of memory chips 50 are stacked and mounted on the pedestal terminal chip 52 via a spacer 51.

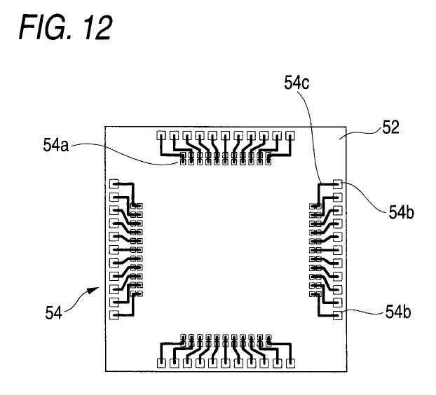

FIG. 12 shows the common pedestal terminal chip 52 on which two memory chips 50 can be mounted. Wiring patterns 54 are formed on the pedestal terminal chip 52. Then, memory chip terminals 54a—to which the terminals 50a of the memory chip 50 to be mounted are connected via the wire 33—are formed on the wiring patterns 54. Then, external connection terminals 54b are formed such that the memory chip terminals 54a are connected and also the terminals 25a of the circuit substrate 25 are connected via the wire 35. The external connection terminals 54b are formed on the peripheral area of the pedestal terminal chip 52 to have the same arrangement as the terminals 25a of the circuit substrate 25.

In the present embodiment, the same memory chips 50 are stacked up to two pieces and mounted on the circuit substrate 25. In case where two memory chips 50 are stacked, the terminals 50a having the same roles are placed in the same positions in the upper and lower memory chips 50. Therefore, as shown in FIG. 12, two memory chip terminals 54a—to which the common terminals 50a of the upper and lower memory chips 50 are connected via the wire 33—are formed on common wirings (for example, 54c) on the pedestal terminal chip 52, and these memory chip terminals are connected to one external connection terminal 54b. Thus, the wiring patterns 54 are formed.

As described above, the circuit substrate 25 and the pedestal terminal chip 52 are prepared. First, the ASIC chip 20 is flip-chip bonded and thus mounted on the circuit substrate 25. Then, the pedestal terminal chip 52 is secured onto the ASIC chip 20 with an adhesive.

Then, the memory chip 50 in the first layer is secured onto the pedestal terminal chip 52 with an adhesive. Then, the terminals 50a of the memory chip 50 and the memory chip terminals 54a of the pedestal terminal chip 52 are connected electrically mutually via the wire 33.

Then, the memory chip 50 in the second layer is secured onto the memory chip 50 in the first layer with an adhesive via the spacer 51. Then, the terminals 50a of the memory chip 50 in the second layer and the memory chip terminals 54a of the pedestal terminal chip 52 are connected electrically mutually via the wire 33.

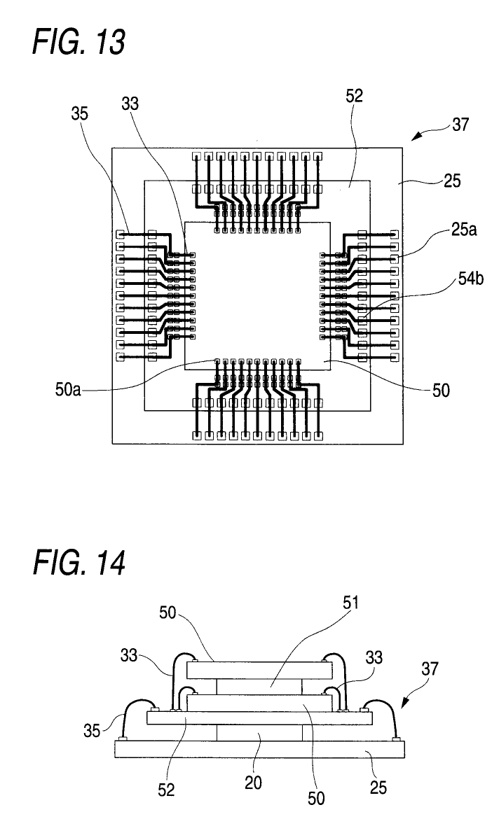

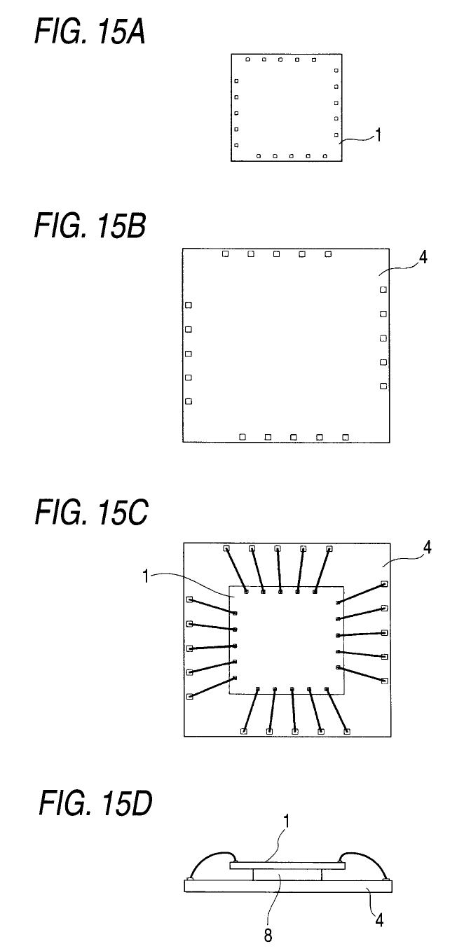

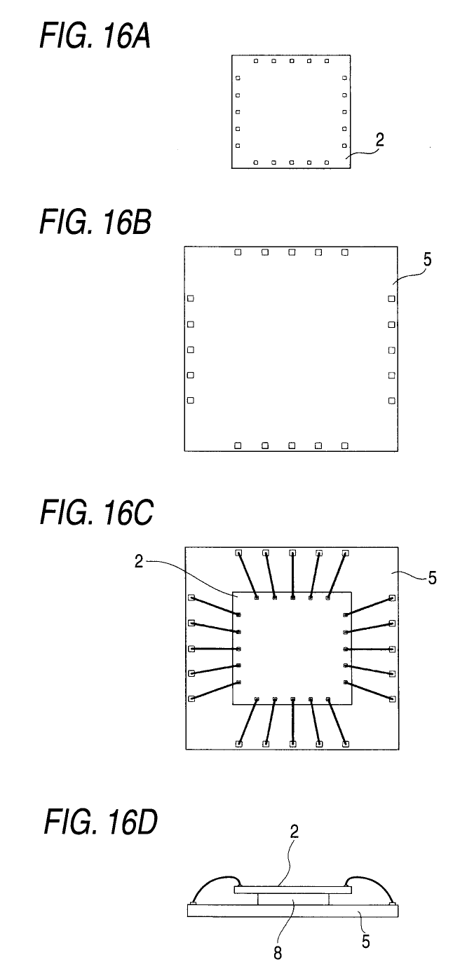

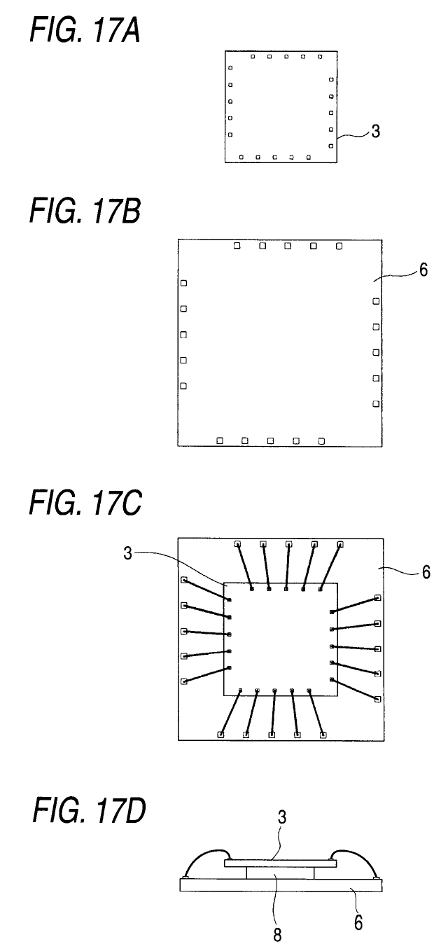

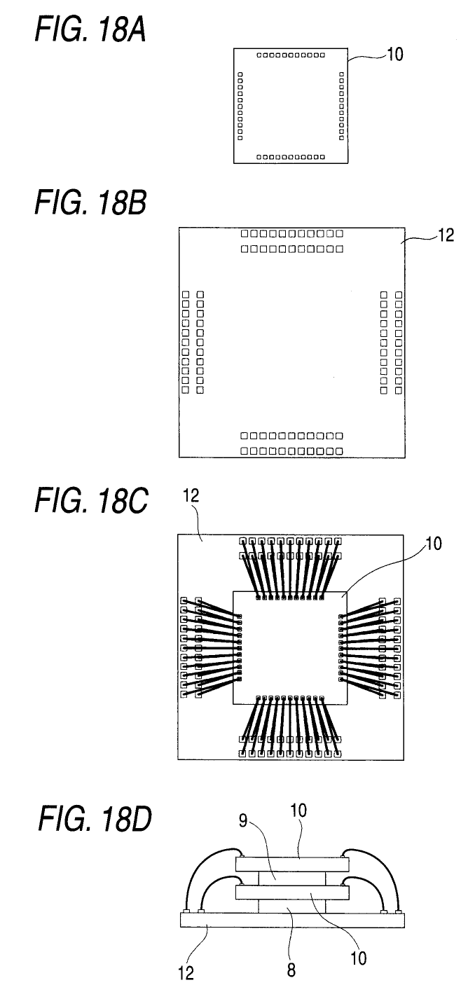

Then, the external connection terminal 54b of the pedestal terminal chip 52 and the terminals 25a of the circuit substrate 25 are connected electrically mutually via the wire 35. Thus, the semiconductor device 37 is completed with respect to respective memory chips (see FIG. 13 and FIG. 14). Here, the ASIC chip 20, the memory chips, and the wires 33 and 35 may be sealed by the sealing resin (not shown).

It is of course that, in case where one memory chip 50 is employed, only the memory chip 50 in the first layer is mounted.

In the above embodiment, while the same memory chips 50 are stacked up to two pieces and mounted, three memory chips 50, or more may be stacked via the spacer and thus mounted. In this case, a plurality of memory chip terminals 54a—to which the terminals 50a of plural memory chips 50 can be connected with the wire 33—are formed on the common wirings 54c.

Here, the same memory chips are not always stacked and mounted, and alternately a plurality of different memory chips can be stacked and mounted. In this case, it is of course that wiring patterns (not shown) on which all memory chips can be mounted are formed on the pedestal terminal chip 52.

While there has been described in connection with the exemplary embodiments of the present invention, it will be obvious to those skilled in the art that various changes and modification may be made therein without departing from the present invention. It is aimed, therefore, to cover in the appended claim all such changes and modifications as fall within the true spirit and scope of the present invention.

What is claimed is:

1. A method of manufacturing a semiconductor device, the method comprising:
a) preparing one type of an ASIC chip;
b) preparing memory chips which are different from each other;
c) preparing a common circuit substrate;
d) preparing a pedestal terminal chip including wiring patterns having memory chip terminals and external connection terminals;
e) mounting the ASIC chip on the common circuit substrate by flip-chip bonding;
f) securing the pedestal terminal chip on the ASIC chip;
g) mounting one of the memory chips on the pedestal terminal chip;
h) electrically connecting terminals on said one of the memory chips to the memory chip terminals using a first wire; and
i) electrically connecting the external connection terminals to terminals on the common circuit substrate using a second wire.

2. A method of manufacturing a semiconductor device, the method comprising the steps of:
a) preparing one type of an ASIC chip;
b) preparing memory chips;
c) preparing a common circuit substrate;
d) preparing a pedestal terminal chip including wiring patterns having memory chip terminals and external connection terminals;
e) mounting the ASIC chip on the common circuit substrate by flip-chip bonding;
f) securing the pedestal terminal chip on the ASIC chip;
g) mounting the memory chips on the pedestal terminal chip;
h) electrically connecting terminals on the memory chips to the memory chip terminals using a first wire; and
i) electrically connecting the external connection terminals to terminals on the common circuit substrate using a second wire.

3. The method of manufacturing a semiconductor device according to claim 2, wherein the step g) comprises:
stacking the memory chips via a spacer.

4. The method of manufacturing a semiconductor device according to claim 2, wherein the step g) comprises:
providing the memory chips in combination.
